(19) United States
(12) Patent Application Publication
(10) Pub. No.: US 2025/0391493 A1
(43) Pub. Date: Dec. 25, 2025

(54) APPARATUSES AND METHODS FOR PRIORITIZED ROW REDUNDANCY REGIONS

(71) Applicant: Micron Technology, Inc., Boise, ID (US)

(72) Inventors: YOSHINORI FUJIWARA, Boise, ID (US); KRISTOPHER J. KOPEL, Boise, ID (US)

(73) Assignee: Micron Technology, Inc., Boise, ID (US)

(21) Appl. No.: 19/227,192

(22) Filed: Jun. 3, 2025

Related U.S. Application Data
(60) Provisional application No. 63/663,820, filed on Jun. 25, 2024.

(51) Int. Cl. G11C 29/00

(52) U.S. Cl. CPC G11C 29/789; G11C 29/702; G11C 29/76

(57) ABSTRACT

A memory device includes a normal memory region and at least two redundant memory regions. The redundant memory regions may have different repair widths from each other. The row decoder may receive a row address and determine if it has been repaired to one or more of the at least two redundant memory regions. The row decoder includes repair logic which determines a priority order of the redundant memory regions. If the address has been repaired to multiple redundant regions, then only the repair in the highest priority one of the multiple redundant regions is used.

### CROSS REFERENCE TO RELATED APPLICATION(S)

This application claims the benefit under 35 U.S.C. § 119 of the earlier filing date of U.S. Provisional Application Ser. No. 63/663,820 filed Jun. 25, 2024 the entire contents of which is hereby incorporated by reference in its entirety for any purpose.

### BACKGROUND

Information may be stored on memory cells of a memory device. The memory cells may be organized at the intersection of word lines (rows) and bit lines (columns). During access operations, the memory accesses information in the memory cells for example to write new information to those memory cells as part of a write operation or to read information from the memory cells as part of a read operation.

One or more memory cells within the memory array may become defective, for example due to a manufacturing issue, damage or wear during use, and so forth. The memory may include redundant memory cells which may be used for repair operations. For example, the redundant memory cells may be located along redundant word lines. Some memories may have different redundant regions, for example which repair different numbers of word lines at a time. There may be a need to prevent conflicts in situations where there may be overlapping repairs.

### BRIEF DESCRIPTION OF THE DRAWINGS

FIG. 1 is a block diagram of a memory system according to some embodiments of the present disclosure.

FIG. 2 is a block diagram of a memory according to some embodiments of the present disclosure.

FIG. 3 is a block diagram of an example implementation of a memory array showing an example set of repair according to some embodiments of the present disclosure.

FIG. 4 is a schematic diagram of a redundancy logic circuit according to some embodiments of the present disclosure.

FIG. 5 is a flow chart of a method according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated (or opened) based on a row address and then selected memory cells along that active word line may have their information read or written to based on which bit lines are accessed, which may be based on a column address. When the access operation is over, the word line may be pre-charged to inactivate (or close) the word line.

The memory includes one or more redundant word lines, each of which intersects a set of redundant memory cells. During an example repair operation, if a word line is identified as defective, the row address which used to be associated with the defective word line may be remapped to the redundant word line instead. In this way, when the row address is received, the redundant word line is accessed instead of the defective word line. The memory includes one or more non-volatile storage elements, such as fuses, anti-fuses, or a combination thereof, which may be used to encode repair information. The memory includes redundant row logic which uses the repair information to determine when to access redundant memory. The repair information from the non-volatile storage elements is stored in repair latches of the redundant row logic. Each repair latch is associated to one or more redundant word lines. When a row address is received, the redundant row logic compares it to the repaired row addresses stored in the repair latches. If there is a match, the redundant row logic directs the memory to access the one or more redundant word lines associated with that repair latch instead of the word line originally mapped to that row address.

Some memory devices may group multiple redundant word lines together into a repair set. This may allow the repair set to share one or more components in the redundant row logic, which may save on space. This may allow a reduction in the logic which checks row addresses to determine if there is a match, as well as a reduction in the amount of bits stored in the repair information. For example, each repair set of word lines may be associated with a repair latch. In this manner, if N redundant word lines are grouped into sets within a redundant region, then that region may have about 1/N latches compared to if those redundant word lines were not part of a set. The repair latches may match a truncated version of the row address, and match any address which shares the truncated portion in common. For example, if the repair width is four, then the repair latch for each repair set will store all but two bits of the row address. If a word line is identified as defective, and a repair is made to a redundant region with sets that have a repair width of four, then a repair may be made on that word line and 3 other word lines which share that portion of the row address in common will also be repaired.

Some memories may have different regions of redundant memory which perform different widths of repair. Each region includes one or more repair sets. The repair sets may be of different numbers of word lines in the different regions. For example, a first region may perform repairs at a first repair width (e.g., 2 word lines) with sets of a first number of word lines each, a second region may perform repairs at a second repair width (e.g., 4 word lines) with sets of a second number of word lines each, a third region may perform repairs at a third repair width (e.g., 8 word lines) with sets of a third number of word lines each and so forth. Certain patterns of repair may cause a conflict. For example, if a group of four word lines is repaired, and then two of those word lines are subsequently repaired again to a two wide region, there may be a conflict since the row address for the two addresses which were repaired again will match with two sets of repair information but the first repair cannot be disabled as the two word lines which were only repaired once still have a valid repair. In order to prevent conflicts between repairs, it may be useful to prioritize repairs.

The present disclosure is drawn to apparatuses, systems, and methods for prioritized row redundancy regions. A memory device may include at least two different redundant regions with different repair widths. Each region includes one or more repair sets of one or more word lines each. The number of word lines in a set is different in the different redundant regions. Each repair set is associated with a repair latch which stores repair information including a row address or a portion thereof. The redundant row logic checks a row address to determine if it matches the repair information in any of the repair latches for the at least regions. The redundant row logic includes a redundancy priority logic circuit. If the row address matches the repair information in the repair latches of multiple of the at least two different redundant regions, the redundancy priority logic circuit selects which region is used and suppresses the other regions based on a priority order. The priority order may help guide how repairs are made in order to ensure that the repairs are properly implemented.

In an example use case, a memory may include a first region of redundant rows which use a repair width of four and a second region of redundant rows which use a repair width of two. The second region is prioritized over the first region if an address matches to repairs in both regions. For example, a row ‘A’ is identified as defective and repaired to the first region. Accordingly, the rows A, B, C, and D are all repaired together to respective word lines of the first region. However, it may later be determined that the redundant word lines used to repair rows C and D are themselves defective. Accordingly, a second repair is performed and rows C and D are repaired again to the second region. If row address C is received, it will match to sets of redundant rows in both regions, to the original repair in the first region (which still properly repairs rows A and B) and to the repair made to the second region. However, because the second region is prioritized when there is more than one match, only the second repair is used, and only the second region is accessed. This prevents two word lines from being activated at the same time.

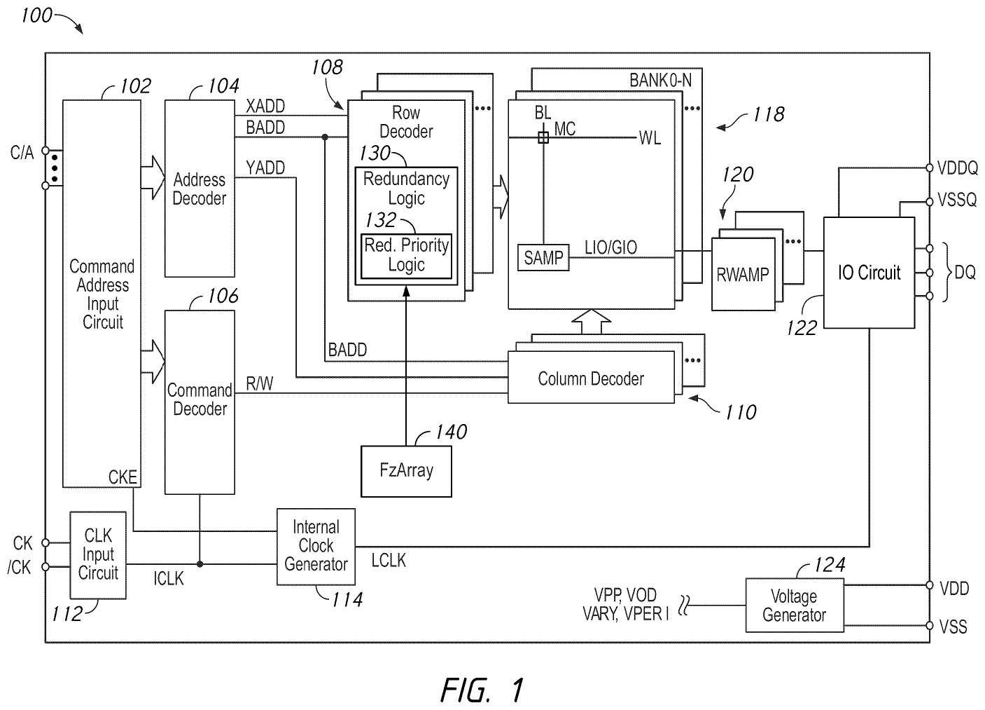

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a controller or host device. The memory receives various commands, data, signals, and voltages (e.g., from the controller).

The semiconductor device 100 includes a memory array 118. The memory array 118 is shown as including a plurality of memory banks. In the embodiment of FIG. 1, the memory array 118 is shown as including N+1 memory banks BANK0-BANKN. More or fewer banks may be included in the memory array 118 of other embodiments. Each memory bank includes a plurality of word lines WL (rows), a plurality of bit lines BL (columns), and a plurality of memory cells MC arranged at intersections of the plurality of word lines WL and the plurality of bit lines BL. Each memory cell stores information. For example, the memory cell may be a capacitive element which stores a bit of information encoded as an amount of charge on the capacitive element.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. When the row decoder 108 activates a word line, the memory cells along that word line are coupled to the bit lines which intersect those memory cells. The bit lines BL are coupled to a respective sense amplifier (SAMP) that senses and amplifies the voltage along the bit line. The column decoder 110 provides a column select signal which determines which bit lines are coupled to local input/output (LIO) and global input/output (GIO) outside of the array 118.

The semiconductor device 100 may employ a plurality of external terminals. The external terminals include command and address (C/A) terminals along a command and address bus to receive commands and addresses. Other external terminals include clock terminals to receive clocks CK and/CK along a clock bus, data terminals DQ to send and receive data along a data bus, and power supply terminals to receive power supply potentials such as VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a read command R or a write command W.

As part of an example read operation, the device 100 may receive a read command along with memory addresses which indicate where the read command should be performed. Responsive to internal commands (such as a row activate command ACT) issued by the command decoder 106, the word line selected by XADD is activated by the row decoder 108 and the data on the memory cells along that word line is amplified onto the intersecting bit lines by sense amplifiers (SAMP). Responsive to internal commands and the column address YADD, the column decoder 110 couples selected bit lines through local and global input/output lines (LIO and GIO) to the read/write amplifiers 120. The read/write amplifiers 120 provide the data to the IO circuit 122, which provides the data along one or more DQ terminals. The data may be provided in synchronization with a data strobe clock DQS.

As part of an example write operation, the device 100 may receive a write command along with memory addresses which indicate where the write command should be performed. The IO circuit 122 receives data along the DQ terminals and provides it to the read write amplifiers 120. Responsive to internal commands (such as a row activate command ACT) issued by the command decoder 106, the word line selected by XADD is activated by the row decoder 108. Responsive to internal commands and the column address YADD, the column decoder 110 couples selected bit lines through local and global input/output lines (LIO and GIO) to the read/write amplifiers 120. The data is provided along the LIO/GIO to the selected bit lines where the sense amplifier SAMP writes the data as a voltage along the intersecting bit line BL to the memory cells at the intersections with the active word line.

The memory device 100 includes a fuse array 140. The fuse array 140 stores information or settings of the memory device 100 in a non-volatile fashion. While generally referred to as a ‘fuse’ array, the fuse array 140 may include any type of non-volatile storage element, such as fuses, anti-fuses, or combinations thereof. The fuse array 140 may be used to store repair information. For example, when a repair is made, the repaired address may be programmed into the fuse array 140. For example, if fuses are used, whether the fuse is blown or not may act as a logical high and low to encode the bits of the address.

The row decoder 108 includes a redundancy logic circuit 130 which determines if a row has been repaired, and if so, directs the row decoder 108 to activate a redundant word line instead of the word line originally associated with the row address. The redundancy logic circuit 130 includes one or more repair latches, each associated with a repair set of redundant word lines. The repair latch stores a row address, or portion thereof, from the fuse array 140. During an example access operation, the redundancy logic 130 compares the row address XADD to the repaired address information from the fuse array 140 loaded in the repair latches. If there is a match, to the address stored in one of the repair latches, the redundancy logic 130 circuit provides a row factor XFactor which indicates the repair set of word lines associated with that repair latch. If there is a match to the address stored in multiple of the repair latches, the redundancy logic circuit 130 provides a row factor XFactor associated with the matching repair latch associated with a repair set in the redundant region with the highest priority. If there is not a match, the redundancy logic circuit uses a row factor associated with a normal (e.g., not redundant) region of the array. The row factor XFactor is a physical address which indicates the physical word line in the array which should be accessed. If the redundancy logic circuit 130 generates the row factor based on a match with repair information, then a redundant word line will be accessed instead of the word line originally mapped to that value of the row address and the row factor associated with the normal word line will be suppressed.

The memory array 118 may have different regions of redundant memory, which may have different repair widths from each other. For example the different regions may have repair sets with different numbers of redundant word lines. In order to save on the number of logic circuits, such as repair latches, used in the redundancy logic 130, the regions may have repair widths greater than one word line, which bundle different row addresses together into a repair set such that if one of those row addresses is repaired, related row addresses are also repaired. The number of row addresses repaired together is the repair width. In an example implementation, the repair width may be based on truncating the amount of the row address which is stored in the fuse array 140 and repair latch and compared to determine if a repair has been made. For example, if the repair width is four, then two bits (e.g., the two LSBs) may be truncated off the row address. Accordingly, any of the four row addresses which share the non-truncated portion in common will match the stored address in the repair latch and thus be repaired to the redundant memory. However, the full address will still be considered when determining which row of redundant memory to activate so that each row address still activates a unique word line.

Some memory devices include multiple different redundant regions, which may have different repair widths from each other. There may be circumstances where overlapping repairs are made, such that a row address matches to multiple redundant regions. The redundancy logic 130 includes a redundancy priority logic circuit 132 which sets a priority of the redundant regions. If a row address matches to multiple regions, the priority logic 132 provides the row factor XFactor for the highest priority region, and suppresses the other matches. In this manner only one word line is activated at a time.

To prevent conflicts, multiple matches within a single redundant region may be forbidden. For example, if for testing purposes the same address is repaired to a single redundant region two or more times, an disable fuse may be blown to prevent all but one of those repairs from being functional. For example, if the disable fuse is blown for a repair, it may not be loaded into a repair latch. Similarly, if an address is repaired a second time to a same region during post-package repair, the original repair may be disabled to prevent conflicts. Thus, while a given address may match two repair sets in two or more different regions, there will be no more than one matching repair set per redundant region.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

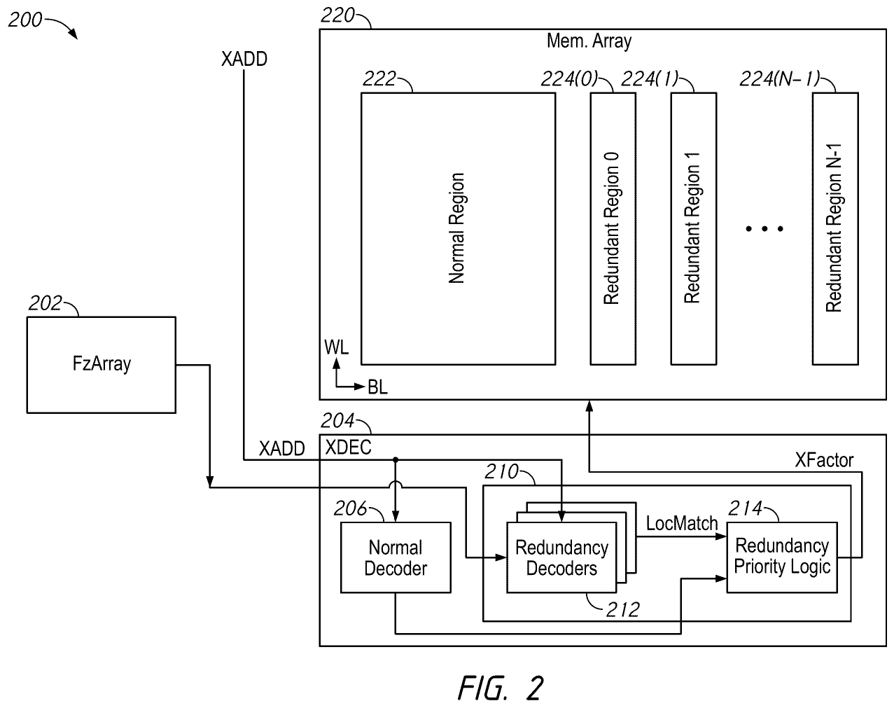

FIG. 2 is a block diagram of a memory according to some embodiments of the present disclosure. The memory 200 of FIG. 2, may, in some embodiments, implement a portion of the memory device 100 of FIG. 1. The view of FIG. 2 shows certain components which may be useful for managing redundancy priority. For the sake of brevity certain other features and components of the memory are not shown in FIG. 2.

The memory 200 includes a memory array 220 (e.g., 118 of FIG. 1) and a row decoder 204 (e.g., 108 of FIG. 1). The memory array 220 includes a normal region 222 and N different redundant regions 224(0) to 224(N−1). The different redundant regions have repair widths which are different from each other. An axis is shown to represent the relative orientation of word lines WL and bit lines BL with respect to FIG. 2. The memory 200 includes a fuse array 202 (e.g., 140 of FIG. 1). The row decoder 204 includes a normal decoder circuit 206 and a redundancy logic circuit 210 (e.g., 130 of FIG. 1). The redundancy logic circuit 210 includes a set of redundancy decoders 212, each of which is associated with one of the redundant regions 224. For example, there may be N redundancy decoders 212. Each redundancy decoder 212 includes the repair latches for the associated redundant region 224. The redundancy logic circuit 210 also includes a redundancy priority logic circuit 214 (e.g., 132 of FIG. 1).

During an access operation, the row decoder 204 receives a row address XADD (e.g., from an address decoder such as 104 of FIG. 1). The normal decoder 206 decodes the row address into a row factor address associated with the normal region 222. The redundancy decoders 212 compare the row address XADD to the repair information stored in the fuse array 202 to determine if the row address has been repaired to a redundant row in their respective redundant region 224. For example, the redundancy decoders 212 include repair latches which are loaded with repaired row addresses (or portions thereof) stored in the fuse array 202. If the row address has not been repaired, then the redundancy logic 210 passes the row factor from the normal decoder 206, and the row decoder 204 will activate a word line in the normal region 222 of the array 220.

If the row address has been repaired, then the row address will be matched to repair information by one or more of the redundancy decoders 212. For example, the row address is compared to the information stored in the repair match to determine if the row address XADD (or portion thereof) matches the repair row address (or portion thereof) stored in any of the repair latches. If there is a match, the redundancy decoder 212 will provide a respective location match signal LocMatch. The redundancy priority logic circuit 214 generates a row factor XFactor based on the one or more location match signals which are active. If only a single location match signal LocMatch is active, then an XFactor is generated indicating the associated redundant region 224 and that row factor is provided instead of the one from the normal decoder 206. If multiple location match signals LocMatch are active, then a row factor XFactor is generated associated with the associated redundant region with the highest priority which is used instead of the row factor from the normal decoder 206. For example, if redundant region 224(0) has a higher priority than redundant region 224(1), then if the row address XADD matches repair information for both redundant regions 224(0) and 224(1), then a row factor will only be provided for redundant region 224(0).

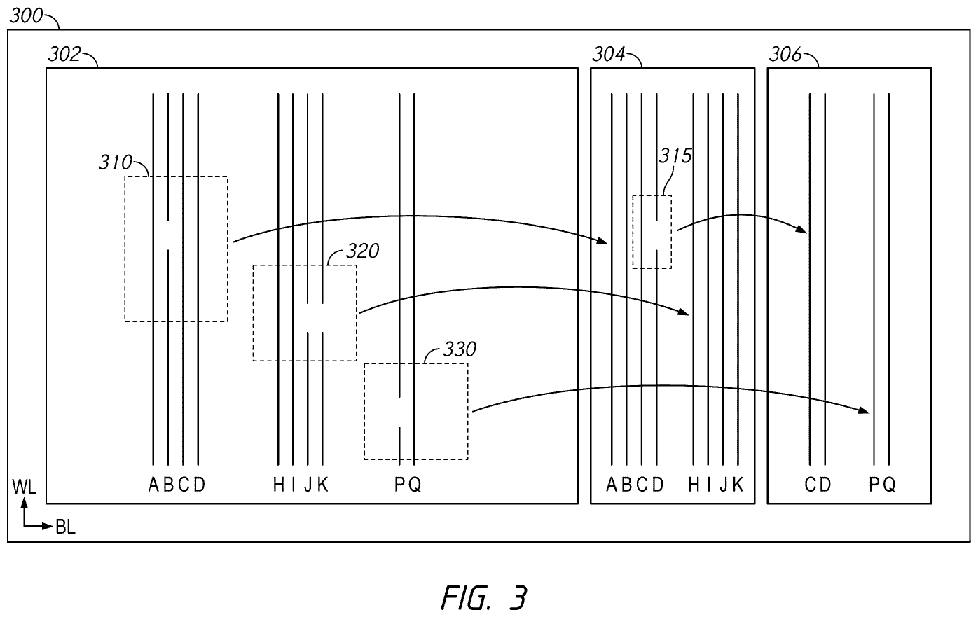

FIG. 3 is a block diagram of an example implementation of a memory array showing an example of repair operations according to some embodiments of the present disclosure. The memory array 300 may, in some embodiments, implement the memory array 118 of FIG. 1, 220 of FIG. 2, or combinations thereof. The memory array 300 shows an example embodiment with a main memory region 302 (e.g., 222 of FIG. 2), and two redundant regions 304 and 306 (e.g., 224 of FIG. 2). The first redundant region 304 has a repair width of four word lines, and the second redundant regions 306 has a repair width of two word lines. Only two example repair sets are shown in each redundant region 304 and 306, however more or fewer repair sets may be used in other example embodiments. In some example embodiments, the redundant regions 304 and 306 may have different numbers of repair sets.

For example repair operations are shown in FIG. 3. Each repair operation is represented as a dotted line box around the set of word lines which are repaired and an arrow pointing to the location where the addresses are repaired to. For the sake of clarity, the row address is shown under the original word line in the main region 302 associated with that row address and under the redundant word line(s) associated with that address after the repair. Row addresses are represented with a letter, such as A, B, C etc.

The first repair 310 is made to a word line associated with row address B. The repair 310 remaps the row address to a repair set in the first redundant region 304. Because the first redundant region has a repair width of four, four addresses are repaired together. For example, stored repair information in the repair latch for the first repair set in the first redundant region 304 may truncate two bits of the row address, and thus match to any of the four row addresses which share all but those two bits in common. Accordingly, any of those four addresses will match the information in the repair latch for that repair set. In this example those four row addresses are represented by the letters A, B, C, and D. Accordingly all four row addresses are remapped to the redundant word lines of a repair set in the first region 304, even though only the word line associated with row address B was identified as having a defect. However, the word line in the first redundant region 304 which the row address D has been remapped to has a defect. Accordingly, a secondary repair 315 is performed. For example, the defect in the word line used to repair row address D may be located at a later time such as during testing or by a customer.

The secondary repair 315 repairs row address D by remapping it to the first repair set in the second redundant memory region 306. Since the second redundant memory region 306 has a repair width of two, the row addresses C and D may both be remapped. For example, the repair information stored in the repair latch for the first repair set in that region 306 may truncate a single bit of the row address and both addresses (e.g., C and D) which share all but that truncated bit in common may be repaired together. In some embodiments, the first repair 310 may be a repair performed in factory environment, while the secondary repair 315 may represent a post-package repair.

Since the rows C and D have been repaired twice, both of those row addresses may match to repair information for both the first and the second redundant region 304 and 306. However, it is not possible to disable the repair made to the first region, as that would also disable the repair of row addresses A and B, which remain valid repairs. When the row addresses C or D are received, they may match with both redundant regions 304 and 306. In the example of FIG. 3, the second redundant region 306 has a higher priority than the first redundant region. Accordingly, when the row addresses C or D are received, the word lines in the second redundant region 306 may be activated, but not the word lines in the first redundant region 304.

Also shown in FIG. 3 are an example second repair 320 and third repair 330. The second repair repairs a different set of row addresses H, I, J, and K to the first redundant region 304 and the third repair 330 repairs two addresses P and Q to the second redundant region 306. Since these repairs only match to a single redundant region, priority is not needed to determine which region to activate.

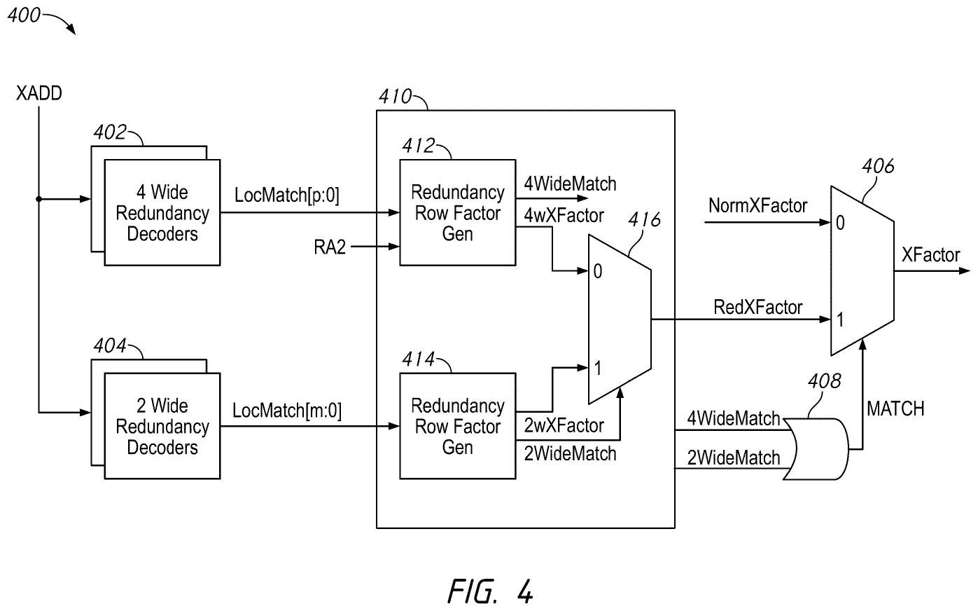

FIG. 4 is a schematic diagram of a redundancy logic circuit according to some embodiments of the present disclosure. The redundancy logic circuit 400 may, in some embodiments, implement the redundancy logic circuit 130 of FIG. 1, 210 of FIG. 2, or combinations thereof. The redundancy logic circuit 400 may be used with an example memory array such as the memory array 300 of FIG. 3 which has two redundant regions, one which has a repair width of four and one which has a repair width of two, where the region with the repair width of two has the higher priority.

The redundancy logic circuit 400 includes a first redundancy decoder 402 and a second redundancy decoder 404 (e.g., 212 of FIG. 2) each associated with a respective first and second redundant region. The redundancy decoders 402 and 404 include the repair latches for the associated redundant region. For example, the redundancy decoders 402 and 404 are shown are stacked boxes to represent that each one represents multiple repair latches, one for each set of redundant word lines in the associated region. The redundancy decoders 402 and 404 receive a row address and provide a respective location match signal LocMatch if the row address matches repair information associated with the respective redundant region. In some embodiments, the two location match signals may have different numbers of bits. For example, the number of bits may be based on the number of bits of the row address which are match for that memory region. In the example of FIG. 4, the location match signal from the first redundancy decoder 402 may have one fewer bit than the location match signal from the second redundancy decoder 404.

The redundancy logic circuit 400 includes a redundancy priority logic circuit 410 (e.g., 132 of Figure, 214 of FIG. 2, or combinations thereof). The redundancy logic circuit 410 provides a match signal MATCH if one or both of the location match signals LocMatch indicated a match and a redundancy row factor indicting the matching redundant region with the highest priority. A multiplexer circuit 406 provides the row factor associated with the normal region NormXFactor (e.g., from normal decoder 206 of FIG. 2) if MATCH is inactive or provides the redundant row factor RedXFactor if MATCH is active.

The redundancy priority logic circuit 410 includes a first redundancy factor generator circuit 412, a second redundancy factor generator circuit 414, and a multiplexer circuit 416. The redundancy factor generator circuits 412 and 414 receive the respective first and second location match signals LocMatch and generate a respective row factor 4wXFactor or 2wXFactor for that redundant region. In some embodiments, the redundancy row factor generator with the greater repair width, in this case the first redundancy row factor generator circuit 412, may receive additional bits of the row address, since its location match signal was based on a truncated version of the row address.

Each redundancy row factor generator circuit 412 and 414 also generates a respective match signal 4wideMatch and 2wideMatch if it provides a row factor. The multiplexer provides the redundant row factor 4wXFactor from the first redundancy row factor generator circuit 412 as the redundant row factor RedXFactor if 2wideMatch is inactive, and provides the redundant row factor 2wXFactor from the second redundancy row factor generator circuit 414 as the redundant row factor RedXFactor if 2wideMatch is active. In this way, even if both row factor generator circuits 412 and 414 are active, the second redundancy row factor generator circuit 414 will have priority.

The signal MATCH is generated by taking the logical OR of 4wideMatch and 2wideMatch. For example, an OR gate 408 receives the two match signals 4wideMatch and 2wideMatch and provides MATCH as an output.

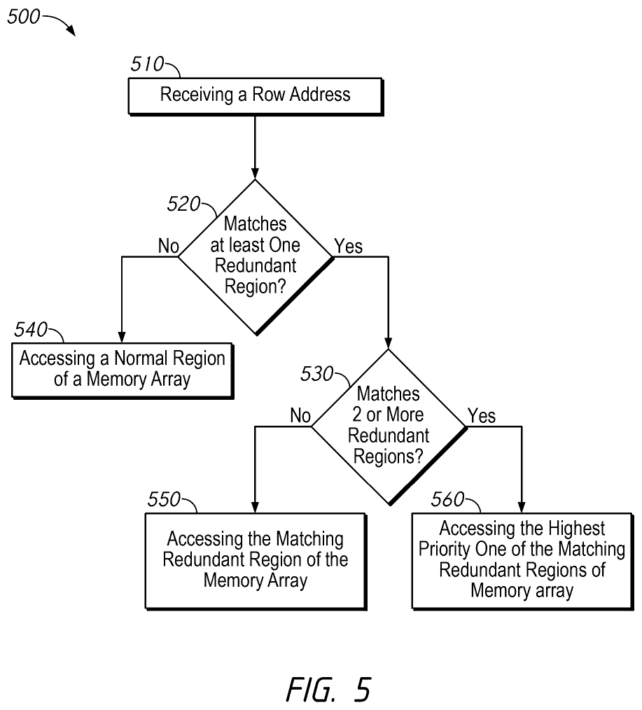

FIG. 5 is a flow chart of a method according to some embodiments of the present disclosure. The method 500 may be implemented by any of the apparatuses or systems described herein. For example, the method 500 may be implemented by a row decoder such as 108 of FIG. 1, 204 of FIG. 2, or combinations thereof.

The method 500 may generally begin with box 510, which describes receiving a row address. The row address may be received as part of an operation such as an access operation or refresh operation. For example, the method 500 may include receive the address from an address decoder (e.g., 104 of FIG. 1) as part of an access operation.

Box 510 may generally be followed by box 520, which describes determining if the row address matches at least one redundant region of a memory array. For example, the method 500 may include comparing the row address to repair information from a fuse array (e.g., 140 of FIG. 1, 202 of FIG. 2, or combinations thereof) with a redundancy logic circuit such as 130 of FIG. 1, 210 of FIG. 2, 400 of FIG. 4, or combinations thereof. For example, the method 500 may include comparing the row address to repair information stored in repair latches. The method 500 may include generating a location match signal for each of the redundant regions that the row address matches with, for example with redundancy decoders such as 212 of FIG. 2, 402/404 of FIG. 4, or combinations thereof. For example, if the row address (or portion thereof) matches the row address (or portion thereof) loaded in a repair latch, the location match signal may be generated.

If the row address does not match any of the redundant regions, for example because it does not match the repair information, the method 500 proceeds bot box 540, which describes accessing a normal region of a memory array. The method 500 may include generating a normal region row factor with a normal region decoder (e.g., 206 of FIG. 2) and using the normal region row factor to access the normal region.

If the row address matches to at least one redundant region, the method 500 proceeds to box 530, which describes determining if the row address matches two or more of the redundant regions.

If the row address matches only one of the redundant regions, for example if the row address matches repair information for only one redundant region, the method 500 proceeds to box 550, which describes accessing the matching one of the redundant regions of the memory array. For example, box 550 may include accessing a word line in the repair set associated with the repair latch which stores the matching the repair information. If the row address matches two or more of the redundant regions, for example if the row address matches repair information for two or more redundant regions the method 500 proceeds to box 560, which describes accessing the word line in a highest priority one of the redundant regions. For example, box 560 may include accessing a word line in the repair set associated with the repair latch which stores the matching repair information and which is associated with the highest priority one of the matching regions.

In an example with two redundant memory regions (e.g., 300 of FIG. 3), the method 500 may include the row address matches repair information associated with a first one of the redundant regions, generating a second row factor if the row address matches repair information associated with a second one of the redundant regions and providing the second row factor if both the first and the second row factor are generated. In this way the second row factor may be the one with priority. The method 500 may also include generating a match signal at an active level if either the first row factor or the second row factor is generated and providing one of the first or the second row factor if the match signal is at the active level or providing a normal row factor if the match signal is at an inactive level.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array including a normal memory region and at least two redundant memory regions;
a fuse array configured to store repair information; and
a row decoder including a redundancy logic circuit configured to access a word line in a highest priority matching redundant memory regions if a row address matches the repair information for more than one of the at least two redundant memory regions.

2. The apparatus of claim 1, wherein the at least two redundant memory regions have different repair widths.

3. The apparatus of claim 2, wherein the at least two redundant memory regions includes a first redundant region with a repair width of four and a second redundant region with a repair width of two, and wherein the second redundant region has priority over the first redundant region.

4. The apparatus of claim 1, wherein the row decoder is configured to access a word line in a matching one of the redundant memory regions if the row address matches the repair information for only one of the at least two redundant memory regions.

5. The apparatus of claim 1, wherein the row decoder is configured to access a word line in the normal memory region if the row address does not match the repair information.

6. The apparatus of claim 1, wherein the redundancy logic circuit includes:
at least two redundancy decoders each associated with a respective one of the at least two redundant memory regions, wherein each of the at least two redundancy decoders is configured provide a respective location match signal if the row address matches the repair information associated with the respective one of the at least two redundant regions;
a redundancy priority logic circuit configured to generate and provide a redundancy row factor associated with the highest priority matching redundant memory region if at least one of the location match signals is provided.

7. The apparatus of claim 6, wherein the redundancy priority logic circuit includes:
a first redundancy row factor generator circuit configured to provide a first match signal at an active level and a first redundancy row factor associated with a first of the at least two redundant regions responsive to a first of the location match signals;
a second redundancy row factor generator circuit configured to provide a second match signal at an active level and a second redundancy row factor associated with a second of the at least two redundant regions responsive to a second of the location match signals; and
a multiplexer configured to provide first redundancy row factor if the second match signal is inactive and to provide the second redundancy row factor if the second match signal is active.

8. The apparatus of claim 7, further comprising a second multiplexer configured to provide a normal redundancy row factor if neither the first nor the second match signal is active and to provide the first or the second redundancy row factor if either the first or the second match signal is active.

9. An apparatus comprising:
a first redundancy decoder configured to provide a first location match signal if a row address matches a first redundant memory region;
a second redundancy decoder configured to provide a second location match signal if the row address matches a second redundant memory region;
a redundancy priority circuit configured to provide a row factor associated with the second redundancy memory region if it receives both the first and the second location match signals.

10. The apparatus of claim 9, wherein the redundancy priority circuit is configured to provide a row factor associated with the first redundancy memory region if it only receives the first location match signal and to provide the row factor associated with the second redundancy memory region if it only receives the second location match signal.

11. The apparatus of claim 9, further comprising a multiplexer circuit configured to provide a row factor associated with a normal memory region if neither the first nor the second location match circuit is provided.

12. The apparatus of claim 9, wherein the redundancy priority circuit includes:
a first redundancy row factor generator circuit configured to provide a first match signal at an active level and a first redundancy row factor associated with the first redundant memory region responsive to a first of the location match signals;
a second redundancy row factor generator circuit configured to provide a second match signal at an active level and a second redundancy row factor associated with the second redundant memory region responsive to a second of the location match signals; and
a multiplexer configured to provide the first redundancy row factor if the second match signal is inactive and to provide the second redundancy row factor if the second match signal is active.

13. The apparatus of claim 12, wherein the first redundancy row factor generator circuit receives an additional bit of the row address compared to the second redundancy row factor generator circuit.

14. The apparatus of claim 9, wherein the first redundant memory region and the second redundant memory region have different repair widths.

15. The apparatus of claim 14, wherein the first redundant memory region has a repair width of four word lines and the second redundant memory region has a repair width of two word lines.

16. A method comprising:
receiving a row address;
determining if the row address matches repair information associated with any of two or more redundant regions of a memory array;
accessing a word line in a normal region of the memory array if the row address does not match the repair information;
accessing a word line in a matching one of the redundant regions if the row address matches repair information associated with only one of the redundant regions; and
accessing a word line in a highest priority matching one of the redundant regions if the row address matches repair information associated with more than one of the redundant regions.

17. The method of claim 16, wherein the two or more redundant regions of the memory array have different repair widths.

18. The method of claim 16, further comprising:
generating a first row factor if the row address matches repair information associated with a first one of the redundant regions;
generating a second row factor if the row address matches repair information associated with a second one of the redundant regions; and
providing the second row factor if both the first and the second row factor are generated.

19. The method of claim 18, further comprising:
generating a match signal at an active level if either the first row factor or the second row factor is generated; and
providing one of the first or the second row factor if the match signal is at the active level or providing a normal row factor if the match signal is at an inactive level.

20. The method of claim 16, further comprising receiving the row address as part of an access operation or a refresh operation.
